(19) United States
(12) Patent Application Publication
(10) Pub. No.: US 2011/0091662 A1
(43) Pub. Date: Apr. 21, 2011

(54) COATING METHOD AND DEVICE USING A PLASMA-ENHANCED CHEMICAL REACTION

(76) Inventors: Matthias Fahland, Dresden (DE); Tobias Vogt, Zittau (DE); Steffen Guenther, Dresden (DE); John Fahlteich, Dresden (DE); Waldemar Schoenberger, Dresden (DE); Alexander Schoenberger, Dresden (DE)

(21) Appl. No.: 12/997,388

(22) PCT Filed: May 15, 2009
(86) PCT No.: PCT/EP09/03479

§ 371 Date: Dec. 10, 2010

(30) Foreign Application Priority Data
Jun. 16, 2008 (DE) 10 2008 028 542.0

(51) Int. Cl. C23C 16/503; C23C 16/515; C23C 16/455; H05H 1/24; C23C 14/34

(52) U.S. Cl. 427/578; 427/569; 118/723 E; 204/192.1

(57) ABSTRACT

The invention relates to a method and a device for the plasma-enhanced deposition of a layer on a substrate (12) by means of a chemical reaction inside a vacuum chamber (11), wherein at least one starting material of the chemical reaction is guided into the vacuum chamber (11) through an inlet (13), and wherein the inlet (13) is connected as an electrode of a gas discharge at least in the region of the inlet opening (18). A magnetron can also be used in the reactive sputtering method.

The invention relates to a method and a device for depositing a layer on a substrate, wherein the deposition process is based on a chemical reaction that is enhanced by a plasma.

In a variety of applications it is usual to coat glass surfaces, film surfaces or also other components in a vacuum. Physical vapor deposition methods are very widespread for this purpose. Methods of this type include, for example, vaporization, in which a coating material is first present in the solid state and is transformed into the gaseous state by heat input.

Another method of physical vapor deposition is sputtering. In this method a plasma is ignited in front of the coating material. Through a suitable electrical wiring and the electrical potential conditions resulting therefrom an ion bombardment of the coating material surface occurs, which leads as a result to the release of particles from the solid bond (sputtering).

Relatively thin layers with high layer thickness precision and a high density and strength can be deposited by means of sputtering. However, in some applications this type of strength of a layer deposited by sputtering tends to be obstructive, such as, for example, in the case of layer systems with an optical function, which are deposited on a flexible plastic substrate. Here the leap in the material properties from the relatively soft and elastic plastic substrate to the harder and inelastic layer system deposited by sputtering causes a crack formation during use. This crack formation is intensified during thermal stress by marked differences in the temperature coefficients of expansion.

In both cited methods of physical vapor deposition the coating material converted into the gaseous state is distributed in the vacuum chamber and is deposited not only on the surface of a substrate to be coated, but also on various surfaces inside the vacuum chamber. However, depending on the method, there is a certain preferred direction in the distribution of the material particles and in the deposition thereof, which is exploited by a suitable positioning of the substrate.

Another group of coating technologies is chemical vapor deposition. In these methods a gaseous substance (also called a monomer) is introduced into a reaction chamber. This gaseous substance can undergo chemical reactions that lead to layer formation (CVD—chemical vapor deposition). This type of chemical reaction can be triggered, for example, by high temperatures on the substrate or by a plasma excitation. This type of method of plasma-enhanced chemical vapor deposition is also referred to as PECVD (plasma enhanced chemical vapor deposition).

PECVD methods that work with a high-frequency plasma or a microwave plasma are widespread. It is characteristic thereby that a process pressure increased compared to the physical vapor deposition prevails in the reaction chamber (1 Pa to 100 Pa compared to 10⁻² Pa to 1 Pa in methods of physical vapor deposition). The simultaneous operation of both processes in a vacuum unit can therefore be carried out technically only with extreme difficulty.

In DE 10 2004 005 313 A1 a method is presented in which layers are deposited successively by sputtering and by PECVD. The PECVD process is thereby realized by a magnetron discharge (also referred to as magnetron PECVD). In DE 10 2004 005 313 A1 an arrangement of two magnetrons is described, which are operated alternately as a cathode and an anode. The special aspect of the method lies in that both processes operate in a comparable pressure range (0.1 Pa to 2 Pa), which renders possible a simultaneous operation and thus the continuous deposition of a multi-layer system. Other sources, such as, e.g., EP 0 815 283 B1, also describe arrangements with only one magnetron. In addition to the adjustment of the pressure range, these methods at the same time also have the advantage of the comparatively easy scalability for large areas.

Despite the adaptation of the pressure conditions, the process chambers for both processes nevertheless must be separate from one another. The reason for this is that the monomer is used up only incompletely in the magnetron PECVD as well as in all other CVD processes and because the unused monomer constituents therefore also fill the reaction chamber when other deposition processes are to be carried out in the reaction chamber. However, other processes, such as, for example, sputtering, should be operated in a manner unaffected by these monomers. That is possible only to a limited extent in particular when the process chambers are separated from one another only by thin gaps in continuously operating line installations. Gaps of this type can only reduce the encroachment of the monomer, but not completely prevent it.

Another problem with magnetron PECVD lies in the partial covering of the electrodes with reaction material, which can lead to process instabilities (arcing). This problem also occurs when only the magnetron PECVD and no further processes are operated in a vacuum chamber.

### OBJECT

The invention is therefore based on the technical problem of creating a method and a device for depositing layers by a plasma-enhanced chemical reaction, by means of which the disadvantages of the prior art can be overcome. In particular, method and device are to make it possible for a higher proportion of the starting materials necessary for the chemical reaction to be converted by a chemical reaction and deposited as layer material. Furthermore, device and method are to be suitable for depositing layers for layer systems with an optical function on flexible plastic substrates.

The solution of this technical problem results from the subject matters with the features of claims 1 and 14. Further advantageous embodiments of the invention are shown by the dependent claims.

In methods and devices according to the invention a layer is deposited onto a substrate by means of a plasma-enhanced chemical reaction in that at least one starting material of the chemical reaction is guided into a vacuum chamber through an inlet, wherein the inlet is connected as an electrode of a gas discharge at least in the region of the inlet opening.

It is realized through an arrangement of this type that a plasma forms in the vicinity of the inlet opening. Since the density of the monomer fed in is higher in the immediate vicinity of the inlet opening than in the center over the entire process chamber, the activation of the monomer in this manner is realized in a particularly effective manner. When the inlet direction of the starting material introduced through the inlet is also directed directly towards the substrate surface to be coated, the particles activated by the plasma are preferably deposited on the substrate. This applies in particular when the process pressure is below 1 Pa during the chemical vapor deposition. In one embodiment therefore the inlet direction of the starting material guided through the inlet is aligned perpendicular to the substrate surface to be coated or at an angular deviation to the perpendicular in a range of ±10°. However, good results are also already achieved in this respect when the angular deviation to the perpendicular is no more than ±20°.

As has already been mentioned, one advantage of the method and devices according to the invention is based on the fact that a plasma is generated in the immediate vicinity of the inlet opening of starting materials of the chemical reaction in that the inlet is connected as an electrode of a gas discharge at least in the region of the inlet opening. An identical result can also be achieved, however, when, for example, an electrically conducting object is connected as an electrode of the gas discharge in the immediate vicinity of the inlet opening. This can be necessary, for example, when the inlet is not electrically conducting in the region of the inlet opening. Thus, for example, an auxiliary electrode positioned directly at the inlet opening can be connected as an electrode of the gas discharge. The statement “connecting the inlet as an electrode of a gas discharge in the region of the inlet opening” should therefore also be understood to cover when an electrically conducting object that is arranged no more than 2 cm from the inlet opening is connected as an electrode of the gas discharge.

The inlet can be connected as an anode or as a cathode of the gas discharge. In one embodiment a magnetron is used to generate the plasma. With a magnetron PECVD process of this type, for example, layers for layer systems with optical function can be advantageously deposited on flexible plastic substrates. If a layer system of this type comprises, for example, a layer sequence in which layers with a high refractive index and layers with a low refractive index alternate, it is advantageous and sufficient if the layers with a low refractive index are deposited with devices and/or methods according to the invention in order, for example, to adjust the material properties of the overall layer system more to the material properties of the flexible plastic substrate and thus to counteract a crack formation during subsequent use.

In a further embodiment, a magnetron connected as a cathode is used to generate a plasma, wherein the inlet is connected as an anode of the gas discharge. The magnetron can be operated hereby with a DC power supply or a pulsed DC power supply.

When a magnetron is used to generate a plasma, however, the magnetron and the inlet can also be connected alternately as cathode and anode. A bipolar power supply unit or also a power supply unit generating pulse packets, for example, can be used as the associated power supply unit for this purpose.

A current supply in the form of pulse packets is particularly suitable, for example, for suppressing the so-called arcing. The success in suppressing arcing is thereby, for example, also dependent on the number of the pulses of a packet and the symmetry of the pulse packets. In order to suppress the arcing, a pulse packet power supply can be adjusted, for example, such that a maximum of 50 pulses can be emitted thereby in a pulse packet when the magnetron is connected as a cathode and that a maximum of 10 pulses can be emitted thereby in a pulse packet when the inlet is connected as a cathode. If the number of pulses of a packet is reduced further, the effect of arc suppression can usually be increased further. It is therefore advantageous when a pulse packet power supply is adjusted such that a maximum of 10 pulses can be emitted thereby in a pulse packet when the magnetron is connected as a cathode and that a maximum of 4 pulses can be emitted thereby in a pulse packet when the inlet is connected as a cathode. The phases in which the inlet is connected as a cathode do not make any noticeable contribution to layer deposition, but serve mainly to clean the magnetron target surface of reaction products. The ratio of pulses in the phase in which the inlet is connected as a cathode, to the number of pulses in the phases in which the magnetron is connected as a cathode, should therefore be in a range of 1:2 to 1:8.

Methods and devices according to the invention can be used with a large number of applications. If, for example, layers with a silicon and water content are deposited, these can be used as solar absorber layers. Boron or phosphorus contents can also be mixed into the starting materials hereby in order to realize the p-conducting partial layer and the n-conducting partial layer, which are located on opposite sides of the intrinsic partial layer of a silicon-containing solar absorber layer.

However, alternative solar absorber layers, so-called CIS layers, can also be deposited according to the invention. In methods of this type, for example, the elements sulfur or selenium are also located in the starting material for the chemical reaction.

Furthermore, devices and methods according to the invention are suitable for depositing smoothing layers in barrier layer systems in which transparent ceramic layers and smoothing layers are alternately deposited in the layer stack.

As already mentioned above, however, layers can also be deposited according to the invention which are a component of a layer system with an optical function. Methods and devices according to the invention can thereby also be embodied only as a part of an installation for depositing the overall layer system. Thus, for example, a layer of the layer system can be deposited with known methods and devices, such as, for example, by sputtering.

### EXEMPLARY EMBODIMENT

The invention is explained in more detail below based on a preferred exemplary embodiment. The figures show:

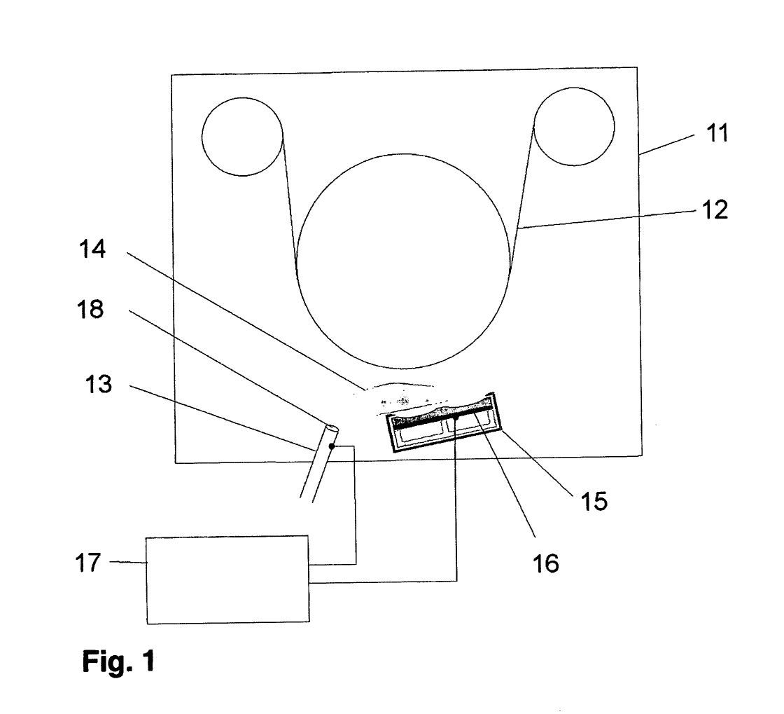

FIG. 1 A diagrammatic representation of a device according to the invention with a magnetron for plasma generation;

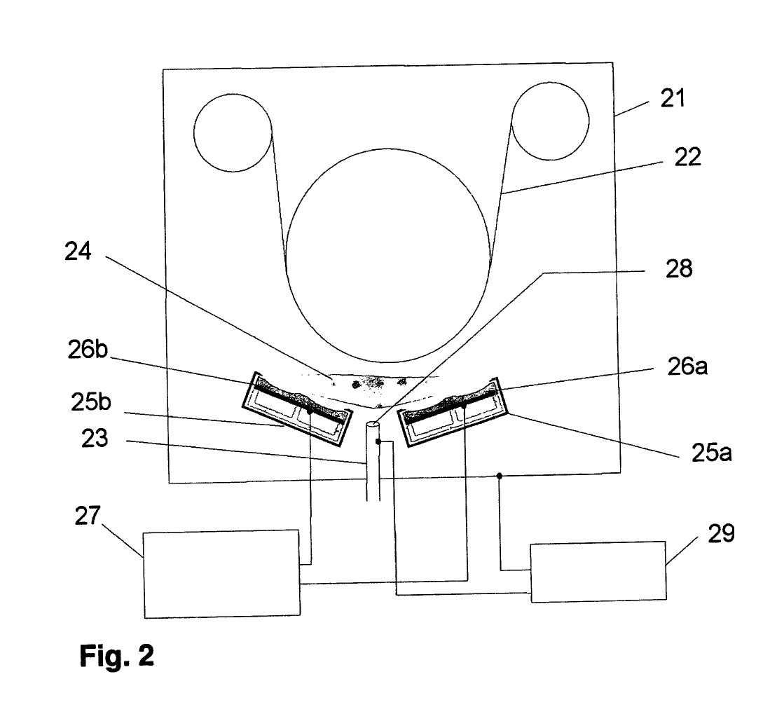

FIG. 2 A diagrammatic representation of an alternative device according to the invention with two magnetrons for plasma generation.

In a vacuum chamber 11 a SiOₓC_{y} layer is to be deposited in a roll-to-roll method on a substrate 12 embodied as a PET film 200 mm wide and 75 μm thick. However, this layer with a low refractive index represents only one layer of a layer system with an optical function, wherein layers with a low refractive index and a high refractive index are arranged alternately in the layer system.

The monomer TEOS as well as the argon gas are introduced into the vacuum chamber 11 by means of an inlet 13. The gas oxygen also reaches the vacuum chamber 11 via an inlet (not shown). A plasma 14 necessary for the PECVD process carried out in the vacuum chamber 11 is generated by means of a magnetron 15. The magnetron 15 is equipped with a titanium target 16, wherein the magnetron 15, however, is operated only to generate the plasma 14. A sputtering of the target 16 or a contribution of the titanium target 16 to the layer structure is not desired, however. The magnetron 14 is therefore operated such that as far as possible no titanium particles are removed from the target 16. Because titanium is sputtered relatively poorly and the sputter yield of titanium oxide is reduced even further with an oxygen-containing plasma, the equipment of a magnetron with a titanium target is particularly suitable in methods and devices according to the invention.

By means of a pulse packet power supply 17 the magnetron 15 and inlet 13 are connected in the region of the inlet opening 18 alternately as a cathode or as an anode of a gas discharge. The region of the plasma 14 with high plasma density therefore does not spread only between the magnetron and the substrate to be coated, as is usual in the prior art, but also extends in the direction of the inlet opening 18. Therefore more monomer constituents are activated by the plasma compared to the prior art, which leads to a higher yield in the layer deposition. The pulse packet power supply 17 has an output of 2 kW and is adjusted such that a maximum of 10 pulses are emitted thereby in a pulse packet when the magnetron 15 is connected as a cathode and that a maximum of 4 pulses are emitted thereby in a pulse packet when the inlet 13 is connected as a cathode. The pulse in time is 9 μs and the pulse out time is 1 μs thereby.

Furthermore, the inlet 13 is aligned such that the inlet direction of the monomer guided into the vacuum chamber 11 through the inlet 13 runs virtually perpendicular to the surface of the substrate 12 to be coated. This alignment likewise makes a contribution to depositing as many monomer constituents as possible as a layer on the substrate 12, whereby undesirable coatings on vacuum chamber components and on the magnetron 15 are reduced at the same time.

An alternative device according to the invention is described in FIG. 2. In a vacuum chamber 21 a SiOₓC_{y} layer 30 nm thick is to be deposited in a roll-to-roll method on a substrate 22 embodied as a PET film 200 mm wide and 75 μm thick. However, this layer with a low refractive index represents only one layer of a layer system with an optical function, wherein layers with a low refractive index and a high refractive index are arranged alternately in the layer system.

The monomer TEOS at 11 g/h as well as the gas argon at 200 sccm are introduced into the vacuum chamber 21 by means of an inlet 23. The gas oxygen at 150 sccm also reaches the vacuum chamber 21 via an inlet (not shown). A plasma 24 necessary for the PECVD process carried out in the vacuum chamber is generated by means of two identical magnetrons 25a and 25b. Each of the magnetrons 25a and 25b is equipped with a titanium target 26a or 26b, wherein the magnetrons 25a, 25b are operated again only to generate the plasma 24.

The magnetron 25a and the magnetron 25b are connected with a frequency of 50 Hz alternately as a cathode or an anode of a gas discharge by means of power supply 27 pulsing in a bipolar manner with an output of 6 kW. At the same time, the inlet 23 arranged between the two magnetrons in the region of its inlet opening 28 is connected as an electrode of a gas discharge by means of a power supply 29.

In this manner the plasma is again intensified in the region between the magnetrons and in the immediate vicinity of the inlet opening 28, whereby more monomer constituents are activated by the plasma compared to the prior art, which in turn leads to a higher yield in the layer deposition.

The power supply 29 connected between the inlet 23 and the electric mass of the vacuum chamber 21 generates unipolar pulses and has an output of 200 W.

Furthermore, the inlet 23 is aligned such that the inlet direction of the monomer guided into the vacuum chamber 21 through the inlet 23 runs virtually perpendicular to the surface of the substrate 22 to be coated. This alignment likewise makes a contribution to depositing as many monomer constituents as possible as a layer on the substrate 22.

1. Method for the plasma-enhanced deposition of a layer on a substrate (12) by means of a chemical reaction inside a vacuum chamber (11), wherein at least one starting material of the chemical reaction is guided into the vacuum chamber (11) through an inlet (13), characterized in that the inlet (13) is connected as an electrode of a gas discharge at least in the region of the inlet opening (18).

2. Method according to claim 1, characterized in that the inlet direction of the starting material is aligned perpendicular to the substrate surface to be coated or at an angular deviation to the perpendicular in a range of ±20°.

3. Method according to claim 1, characterized in that the inlet is connected as an anode of the gas discharge.

4. Method according to claim 1, characterized in that a magnetron (13) is used to generate the plasma.

5. Method according to claim 4, characterized in that the magnetron is connected as a cathode and the inlet is connected as an anode of the gas discharge.

6. Method according to claim 5, characterized in that the magnetron is operated with a DC power supply or a pulsed DC power supply.

7. Method according to claim 4, characterized in that the magnetron (15) and the inlet (13) are operated alternately as a cathode and associated anode of the gas discharge, wherein the magnetron (15) is fed by means of a pulse packet power supply (17).

8. Method according to claim 1, characterized in that in addition to the starting material for the chemical reaction a further gas is guided through the inlet (13) into the vacuum chamber (11).

9. Method according to claim 1, characterized in that a silicon-containing layer is deposited, which additionally contains hydrogen constituents.

10. Method according to claim 1, characterized in that the layer is deposited as a smoothing layer of a barrier layer system in which a transparent ceramic layer and a smoothing layer are alternately deposited.

11. Method according to claim 1, characterized in that a starting material is used that contains sulfur or selenium.

12. Method according to claim 1, characterized in that the layer is deposited as a component of a layer system, wherein at least one other layer of the layer system is deposited by magnetron sputtering.

13. Method according to claim 1, characterized in that the magnetron (15) is electrically coupled with a pulse packet power supply (17), from which a maximum of 50 pulses are emitted in a pulse packet when the magnetron is connected as a cathode, and from which a maximum of 10 pulses are emitted in a pulse packet when the inlet is connected as a cathode.

14. Device for depositing a layer on a substrate (12) by means of a chemical reaction in a vacuum chamber (11) comprising a device for generating a plasma (14) and at least one inlet (13), through which a starting material of the chemical reaction can be admitted into the vacuum chamber (11), characterized in that the inlet (13) is connected as an electrode of a gas discharge at least in the region of the inlet opening (18).

15. Device according to claim 14, characterized in that the inlet direction of the starting material is aligned perpendicular to the substrate surface to be coated or at an angular deviation to the perpendicular in a range of ±20°.

16. Device according to claim 14, characterized in that the device for generating the plasma comprises at least one magnetron (15).

17. Device according to claim 16, characterized in that the magnetron is connected as a cathode and the inlet is connected as an anode of the gas discharge.

18. Device according to claim 17, characterized in that the magnetron is electrically coupled with a DC power supply or a pulsed DC power supply.

19. Device according to claim 16, characterized in that the magnetron (15) and the inlet (13) are alternately connected as a cathode and associated anode of the gas discharge.
